(19) United States
(12) Patent Application Publication
(10) Pub. No.: US 2015/0214466 A1
(43) Pub. Date: Jul. 30, 2015

(54) VIBRATION GENERATING APPARATUS FOR PORTABLE TERMINAL

(71) Applicant: SAMSUNG ELECTRO-MECHANICS CO., LTD., Suwon-Si (KR)

(72) Inventors: Dong Sun PARK, Suwon-Si (KR); Jung Hyun Park, Suwon-Si (KR); Jong Woo Hong, Suwon-Si (KR); Dong Woohn Kim, Suwon-Si (KR); Viatcheslav Smirnov, Suwon-Si (KR)

(73) Assignee: SAMSUNG ELECTRO-MECHANICS CO., LTD., Suwon-Si (KR)

(21) Appl. No.: 14/582,182

(22) Filed: Dec. 24, 2014

(30) Foreign Application Priority Data
Jan. 28, 2014 (KR) 10-2014-0010140

(51) Int. Cl. H01L 41/09; H01L 41/053

(52) U.S. Cl. CPC H01L 41/0973; H01L 41/053

(57) ABSTRACT

The vibration generating apparatus includes: a diaphragm formed of a metal; a piezoelectric plate mounted on at least one surface of the diaphragm; a fixed member coupled to the diaphragm along an outer circumference of the diaphragm to fix the diaphragm; and wherein the fixed member is formed of a material having a Young's modulus lower than that of steel.

### CROSS-REFERENCE TO RELATED APPLICATION

This application claims the benefit of Korean Patent Application No. 10-2014-0010140 filed on Jan. 28, 2014, with the Korean Intellectual Property Office, the disclosure of which is incorporated herein by reference.

### BACKGROUND

The present disclosure relates to a vibration generating apparatus for a portable terminal.

A vibration generating apparatus, a device converting electrical energy into mechanical vibrations using the principle of the generation of electromagnetic force, is mounted in a mobile phone to thereby be used for silently notifying a user of call reception by transferring vibrations thereto.

In addition, in accordance with the rapid growth in the mobile phone market, various functions have been added to mobile phones. As mobile phone components have been required to have a small size and high quality, in accordance with this trend, the development of vibration generating apparatuses having novel structures capable of overcoming the disadvantages of existing vibration generating apparatuses and having significantly improved quality has been demanded.

Recently, as the release of mobile phones having large liquid crystal display (LCD) screens has rapidly increased, a touchscreen scheme has been adopted therein. As a result, vibration generating apparatuses have been used in order to generate vibrations at the time of a touch interaction with such a touchscreen.

Further, in vibration generating apparatuses used in mobile phones having a touchscreen, an operational lifespan should be increased, since the amount of vibrations generated at the time of touch interactions with the touchscreen is greater than that of vibrations generated at the time of call reception, and a response speed of vibrations should be increased in accordance with a speed of touch interactions with the touchscreen.

In accordance with demands for the above-mentioned lifespan and response characteristics, a linear type vibration generating apparatus has mainly been used in mobile phones having touchscreens.

The linear type vibration generating apparatus may generate vibrations in a scheme of moving a mover suspended from a spring by electromagnetic force between a coil and a magnet using a weight body connected to an elastic member installed in a vibrator using linear resonance rather than using a rotational principle of a motor.

Alternatively, a piezoelectric element may be used as an actuator to provide the mover with linear resonance through contraction and expansion of the piezoelectric element, thereby generating vibrations.

In the case in which a piezoelectric actuator using the piezoelectric element is used in the vibration generating apparatus, a principle in which lengths of a piezoelectric plate are changed on both sides of the piezoelectric plate in a length direction, based on a center of the piezoelectric plate, has been used.

Most piezoelectric plates according to the related art have been manufactured to have an elongated bar shape. However, in this case, there is a disadvantage that a size of the piezoelectric plate may be relatively large, such that there may be a limitation in mounting the piezoelectric plate in a mobile terminal required to be miniaturized and thinned.

Therefore, a piezoelectric plate that may be easily mounted in a compact, thin mobile terminal has been demanded.

### RELATED ART DOCUMENT

(Patent Document 1) U.S. Patent Application Publication No. 20060119586

### SUMMARY

An aspect of the present disclosure may provide a piezoelectric plate for a mobile terminal capable of being formed in a disk shape rather than a bar shape.

According to an aspect of the present disclosure, a vibration generating apparatus may include: a diaphragm formed of a metal; a piezoelectric plate mounted on at least one surface of the diaphragm; a fixed member coupled to the diaphragm along an outer circumference of the diaphragm to fix the diaphragm; and wherein the fixed member is formed of a material having a Young's modulus lower than that of steel.

The fixed member may be formed of rubber.

The vibration generating apparatus may further include a housing coupled to the fixed member and accommodating the diaphragm in an internal space thereof.

The vibration generating apparatus may be a bimorph type piezoelectric element in which the piezoelectric plates are mounted on both surfaces of the diaphragm.

The fixed member may be a housing accommodating the diaphragm in an internal space thereof.

The diaphragm may be formed of a material having a Young's modulus lower than that of the steel.

The diaphragm may be formed of steel, brass, or Invar.

A resonant frequency fr of vibrations generated by the diaphragm and the piezoelectric plate may satisfy the following Conditional Equation 1:

150 Hz≦fr≦500 Hz Conditional Equation 1

A thickness Dt of the diaphragm may satisfy the following Conditional Equation 2:

0.06 mm≦Dt≦0.1 mm Conditional Equation 2

The diaphragm may be formed in a disk shape.

The piezoelectric plate may be formed in a disk shape having concentricity with respect to the diaphragm.

The fixed member may be formed in a circular ring shape corresponding to a shape of the outer circumference of the diaphragm.

According to another aspect of the present disclosure, a vibration generating apparatus may include: a diaphragm formed of a metal and formed to a thickness of 0.1 mm or less; a piezoelectric plate mounted on at least one surface of the diaphragm; and a fixed member coupled to the diaphragm along an outer circumference of the diaphragm to fix the diaphragm, wherein the diaphragm is formed of a material having a Young's modulus lower than that of steel.

The diaphragm may be formed of brass or Invar.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a vibration generating apparatus according to an exemplary embodiment in the present disclosure;

FIG. 2 is an exploded perspective view schematically illustrating the vibration generating apparatus of FIG. 1;

FIG. 3 is an exploded perspective view schematically illustrating a piezoelectric plate of FIG. 2;

FIG. 4 is a cross-sectional view taken along line A-A′ of FIG. 1;

FIG. 5 is a cross-sectional view schematically illustrating a vibration generating apparatus according to another exemplary embodiment in the present disclosure;

FIG. 6 is a cross-sectional view schematically illustrating a vibration generating apparatus according to another exemplary embodiment in the present disclosure;

FIG. 7 is a cross-sectional view schematically illustrating a vibration generating apparatus according to another exemplary embodiment in the present disclosure; and

FIG. 8 is a cross-sectional view schematically illustrating a vibration generating apparatus according to another exemplary embodiment in the present disclosure.

### DETAILED DESCRIPTION

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

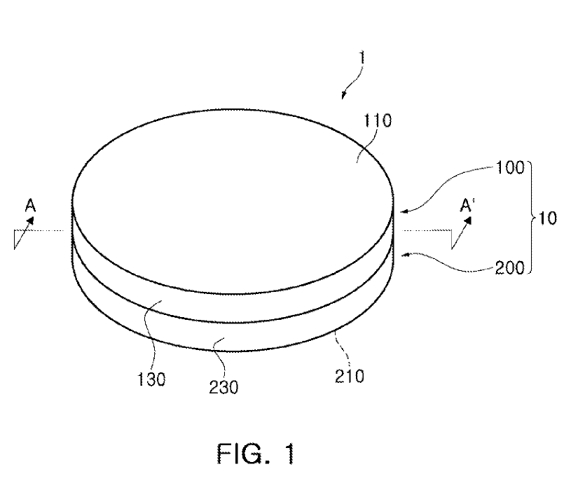

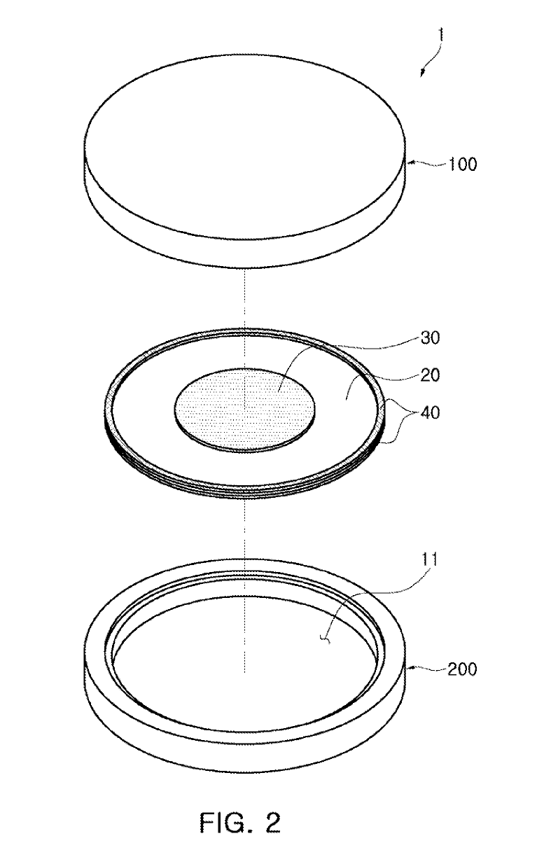

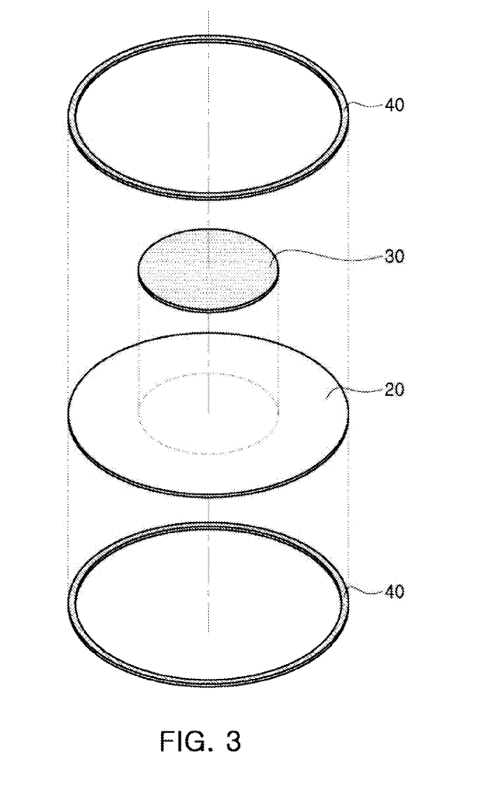

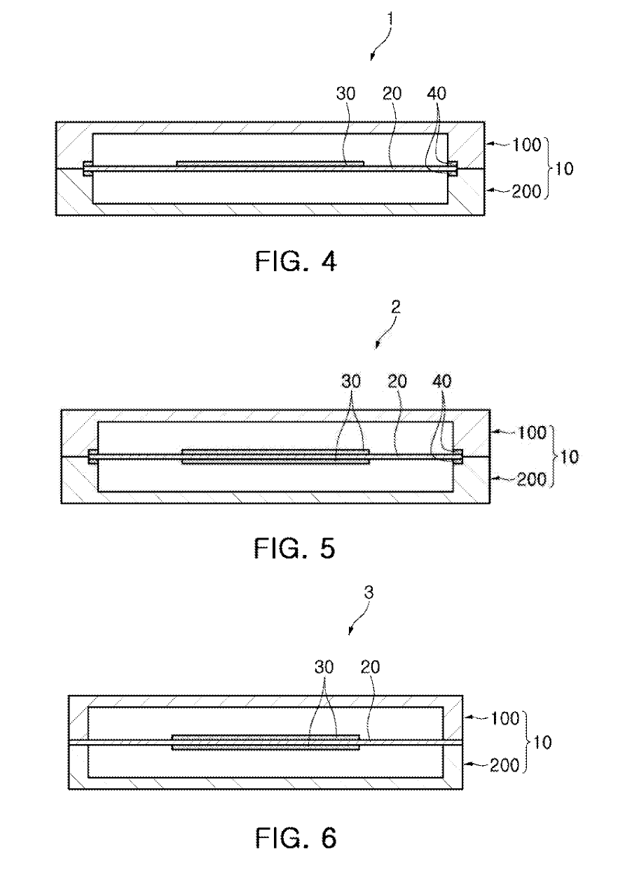

FIG. 1 is a perspective view schematically illustrating a vibration generating apparatus according to an exemplary embodiment in the present disclosure; and FIG. 2 is an exploded perspective view schematically illustrating the vibration generating apparatus of FIG. 1. In addition, FIG. 3 is an exploded perspective view schematically illustrating a piezoelectric plate of FIG. 2; and FIG. 4 is a cross-sectional view taken along line A-A′ of FIG. 1.

Referring to FIGS. 1 through 4, a vibration generating apparatus 1 according to the present exemplary embodiment may be a vibration generating apparatus using a membrane type piezoelectric plate and may include a housing 10 having an internal space 11, a diaphragm 20, a piezoelectric plate 30 provided on at least one surface of the diaphragm 20 and providing driving force for moving the diaphragm 20 vertically, and a fixed member 40.

The housing 10 may have a cylindrical shape as shown in FIGS. 1 and 2. However, the housing 10 is not limited to having the cylindrical shape, but may have various shapes such as a rectangular pillar shape, a hexahedral shape, or the like.

The housing may be divided into an upper housing 100 and a lower housing 200 depending on an assembly scheme thereof. In this case, the upper housing 100 and the lower housing 200 may be formed in shapes that are the same as or similar to each other and may be coupled to each other while facing each other.

In the case in which the upper and lower housings 100 and 200 have the same shape, since the upper and lower housings 100 and 200 may be simultaneously produced in a single manufacturing line, productivity may be improved and a manufacturing cost may be decreased.

In an exemplary embodiment in the present disclosure, the internal space 11 may be formed by combining the upper and lower housings 100 and 200 with each other. Here, the internal space 11 may be used as a space in which a diaphragm 20 and a piezoelectric plate 30 to be described below vibrate.

The upper and lower housings 100 and 200 may have main surfaces 110 and 210 and sides 130 and 230 defining a height of the housing, respectively. The upper and lower housings 100 and 200 may form the internal space 11 by combination therebetween. In this case, heights of the sides 130 and 230 may define a height of the internal space 11.

The diaphragm 20 may be provided in a form in which it transverse the internal space 11 of the housing 10 and may divide the internal space 11 into an upper space and a lower space.

The diaphragm 20 may be formed of a unimorph type piezoelectric element in which a piezoelectric plate expanded and contracted in a plane direction may be adhered to one surface of a resin plate or a metal plate, a bimorph type piezoelectric element in which piezoelectric plates expanded and contracted in opposite directions may be adhered to both surfaces of a resin plate or a metal plate, and a bimorph type piezoelectric element in which a multilayer piezoelectric plate bent and deformed in itself may be adhered to one surface of a resin plate or a metal plate. Furthermore, the entire diaphragm may be formed of a multilayer piezoelectric element. The diaphragm 20 may be any type diaphragm as long as it may be bent and vibrate in a thickness direction of the plate by applying an alternate voltage (a sinusoidal voltage or a rectangular wave voltage) to the piezoelectric plate.

The diaphragm 20 according to the present exemplary embodiment may be formed in a disk shape. Therefore, the diaphragm 20 may be easily coupled to the housing 10 having the cylindrical shape. In more detail, the diaphragm 20 may be coupled to the housing 10 while being fitted between an upper edge 131 and a lower edge 231 at which the upper and lower housings 100 and 200 are combined with each other. That is, the diaphragm 20 may be fitted into portions at which the side 130 of the upper housing 100 and the side 230 of the lower housing 200 are combined with each other.

In an exemplary embodiment in the present disclosure, the piezoelectric plate 30 may be provided on at least one surface of the diaphragm 20 and may provide the driving force vertically moving the diaphragm 20. The piezoelectric plate 30 may be configured of a piezoelectric element and an electrode and use a principle that a length of the piezoelectric element is changed at the time of applying a voltage thereto.

In the present exemplary embodiment, the piezoelectric plate 30 may be mounted on one surface or both surfaces of the diaphragm 20.

In addition, according to the present exemplary embodiment, a circuit board connected to the electrode provided in the piezoelectric plate 30 may be provided to supply power to the piezoelectric plate 30. Here, the circuit board may be a printed circuit board (PCB) or a flexible flat cable (FFC), but is not limited thereto.

In the present exemplary embodiment, the piezoelectric plate 30 may be formed in a disk shape, similar to the diaphragm 20, and be mounted on the diaphragm 20. Here, the piezoelectric plate 30 may be disposed at the center of the diaphragm 20 to have the concentricity with the diaphragm 20.

In addition, the piezoelectric plate 30 may have a diameter smaller than that of the diaphragm 20, for example, a diameter corresponding to about a half of that of the diaphragm 20. However, the present disclosure is not limited thereto.

The fixed member 40 may be coupled to the diaphragm 20 along an outer peripheral edge of the diaphragm 20 to fix the diaphragm 20. Therefore, the fixed member 40 may be formed in a ring shape corresponding to a shape of an outer circumference of the diaphragm 20.

In the present exemplary embodiment, the case in which the diaphragm 20 is formed in the disk shape has been described by way of example. Therefore, the fixed member 40 may also be formed in a circular ring shape corresponding to the disk shape.

The fixing member 40 may be formed of various materials, particularly, rubber.

The vibration generating apparatus 1 according to the present exemplary embodiment configured as described above may be used in a portable terminal such as a mobile phone to transfer vibrations such as a touch feedback, or the like, to a user of the portable terminal.

However, strength of the vibrations needs to be secured in order to allow a user to feel the touch feedback. To this end, in the vibration generating apparatus 1 according to the present exemplary embodiment, a resonant frequency fr may preferably satisfy the following Conditional Equation 1.

150 Hz≦fr≦500 Hz Conditional Equation 1

That is, the vibration generating apparatus 1 according to the present exemplary embodiment may be configured so that the resonant frequency of the vibrations is generated in a range of 150 to 500 Hz. The reason is that a user may best feel tactile sensations when the resonant frequency of the plate is in the above-mentioned range.

Therefore, the vibration generating apparatus 1 according to the present exemplary embodiment may be configured so that the resonant frequency is positioned in the range of 150 to 500 Hz, while having the above-mentioned configuration.

To this end, the diaphragm 20 according to the present exemplary embodiment may be formed of a metal, more specifically, a metal having a Young's modulus lower than that of steel.

For example, the diaphragm 20 may be formed of brass or Invar.

The steel may have a Young's modulus of 2.00×10¹¹ N/m², brass may have a Young's modulus of 1.15×10¹¹ N/m², and Invar may have a Young's modulus of 1.45×10¹¹ N/m².

Therefore, in the case of using brass or Invar, the diaphragm 20 having the Young's modulus lower than that of the steel may be easily implemented.

In addition, the diaphragm 20 according to the present exemplary embodiment may be formed to a thickness of 0.1 mm or less. In detail, a thickness Dt of the diaphragm 20 according to the present exemplary embodiment may satisfy the following Conditional Equation 2.

0.06 mm≦Dt≦0.1 mm Conditional Equation 2

In the case in which the diaphragm 20 is formed to a thickness less than 0.06 mm, the thickness of the diaphragm 20 may be excessively thin, such that vibrations are not appropriately generated. In addition, in the case in which the diaphragm 20 is formed to a thickness exceeding 0.1 mm, a resonant frequency may become high, such that it is difficult to provide the resonant frequency Fr in the above-mentioned allowable range.

In addition, in the case in which the fixed member 40 according to the present exemplary embodiment is formed of a material having a Young's modulus lower than that of the steel, there may be an effect in which the resonant frequency Fr is reduced. To this end, in the case of the present exemplary embodiment, the fixed member 40 may be formed of the rubber as described above having the Young's modulus of 2.00×10⁰⁵ N/m².

The following Table 1 and Table 2 provide measurement data of resonant frequencies depending on materials and thicknesses of the fixed member 40 and the diaphragm 20. Here, Table 1 provides measurement data of resonant frequencies in the case in which the fixed member 40 is formed of the steel, and Table 2 provides measurement data of resonant frequencies in the case in which the fixed member 40 is formed of the rubber.

In addition, in measuring the resonant frequencies, the diaphragm 20 was configured to have a diameter of 30 mm, the piezoelectric plate 30 was configured to have a diameter of 15 mm and a thickness of 1 mm, and a horizontal width of the fixed member 40 contacting the diaphragm 20 was set to 1 mm.

TABLE 1
Material of Fixed Member: Steel

Thickness

| Material | 0.08 mm | 0.10 mm |
|---|---|---|
| Brass | 691 Hz | 841 Hz |
| Invar | 744 Hz | 900 Hz |
| Steel | 836 Hz | 996 Hz |

TABLE 2
Material of Fixed Member: Rubber

Thickness

| Material | 0.08 mm | 0.10 mm |
|---|---|---|
| Brass | 346 Hz | 422 Hz |
| Invar | 371 Hz | 451 Hz |
| Steel | 425 Hz | 510 Hz |

First referring to Table 1, it may be appreciated that in the vibration generating apparatus 1 according to the present exemplary embodiment, a resonant frequency is larger than 500 Hz regardless of a thickness of the diaphragm 20 in the case in which the fixed member 40 is formed of the steel. Therefore, in the case in which the fixed member 40 is formed of the steel, the resonant frequency may become high, such that it is difficult to provide satisfactory vibrations to a user.

On the other hand, it may be appreciated that a resonant frequency is generally 500 Hz or less in the case in which the fixed member 40 is formed of the rubber, as shown in Table 2. However, it may be appreciated that a resonant frequency is larger than 500 Hz in the case in which the diaphragm 20 is formed of a steel plate having a thickness of 0.1 mm.

Therefore, in the case in which the diaphragm 20 is formed to a thickness of 0.1 mm, when the diaphragm 20 is formed of brass or Invar, a resonant frequency may be present in the allowable range.

In addition, it may be appreciated that the diaphragm 20 may be formed of the steel as well as brass or Invar in the case in which the diaphragm 20 is formed to a thickness of 0.8 mm.

In detail, in the vibration generating apparatus 1 according to the present exemplary embodiment, in the case in which the fixed member 40 is formed of the rubber and the diaphragm 20 is formed at the thickness of 0.1 mm, the diaphragm 20 may be formed of a material having a Young's modulus lower than that of the steel to implement the resonant frequency to be in the allowable range (150 to 500 Hz).

In addition, in the case in which the diaphragm 20 is formed to a thickness thinner than 0.1 mm, even though the diaphragm 20 is formed of the steel, the resonant frequency may be implemented to be in the above-mentioned allowable range.

Since the vibration generating apparatus 1 according to an exemplary embodiment in the present disclosure configured as described above may be formed in the disk shape rather than a bar shape, it may be miniaturized as compared with the related art. Therefore, the vibration generating apparatus 1 according to an exemplary embodiment in the present disclosure may be easily mounted in a compact, thin portable terminal.

In addition, since the vibration generating apparatus 1 according to an exemplary embodiment in the present disclosure may vibrate at the resonant frequency at which a user may best feel the tactile sensation in spite of having a small size, it may provide the satisfactory touch feedback to a user.

Meanwhile, the vibration generating apparatus according to the present exemplary embodiment is not limited to a configuration of the above-mentioned exemplary embodiment, but may be variously modified.

FIG. 5 is a cross-sectional view schematically illustrating a vibration generating apparatus according to another exemplary embodiment in the present disclosure.

Referring to FIG. 5, a vibration generating apparatus 2 according to the present exemplary embodiment may be formed a bimorph type piezoelectric element in which the piezoelectric plates 30 are formed on both surfaces of the diaphragm 20. In the case in which the vibration generating apparatus 2 is implemented as the bimorph type piezoelectric element, driving force of the vibration generating apparatus 2 may be increased, such that strength of vibrations may be further secured.

FIG. 6 is a cross-sectional view schematically illustrating a vibration generating apparatus according to another exemplary embodiment in the present disclosure.

Referring to FIG. 6, in a vibration generating apparatus according to the present exemplary embodiment, the above-mentioned fixed member 40 (See FIG. 5) may be omitted, and the diaphragm 20 may be directly coupled to the housing 10. In this case, the housing 10 may fix the diaphragm while contacting the diaphragm 20, similar to the above-mentioned fixed member 40. That is, the housing may also perform a function of the fixed member 40.

To this end, the housing 10 according to the present exemplary embodiment may be wholly or partially formed of rubber. That is, at least a portion of the housing 10 contacting the diaphragm 20 may be formed of the rubber.

In this case, since a process of coupling the fixed member to the diaphragm 20 may be omitted in a manufacturing process of the vibration generating apparatus 3, the vibration generating apparatus 3 may be easily manufactured.

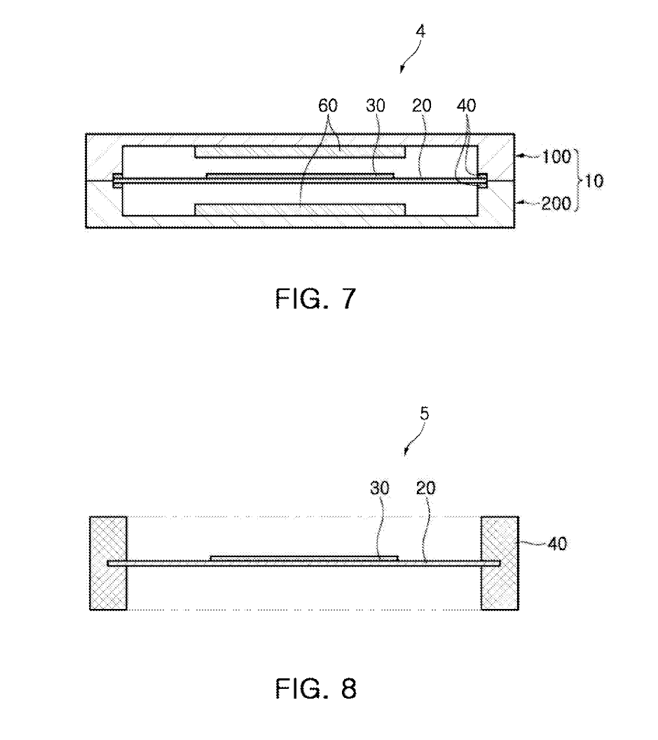

FIG. 7 is a cross-sectional view schematically illustrating a vibration generating apparatus according to another exemplary embodiment in the present disclosure.

Referring to FIG. 7, a vibration generating apparatus 4 according to the present exemplary embodiment may have a buffering member 60 disposed in the housing 10. The buffering member 60 may be attached to an inner surface of the housing 10 in a form in which it faces the piezoelectric plate 30. Here, the buffering member 60 may be formed of any material that may absorb impacts, such as rubber, sponge, or the like.

In the case in which the vibration generating apparatus 4 includes the buffering member 60 as described above, damage to the piezoelectric plate 30 due to a direct contact between the piezoelectric plate 30 and the housing 10 may be significantly decreased.

FIG. 8 is a cross-sectional view schematically illustrating a vibration generating apparatus according to another exemplary embodiment in the present disclosure.

Referring to FIG. 8, in a vibration generating apparatus 5 according to the present exemplary embodiment, the housing according to the above-mentioned exemplary embodiments may be omitted, and only the fixed member 40 may be used.

In the vibration generating apparatus 5 according to the present exemplary embodiment, the diaphragm 20 may be coupled to the fixed member 40, and the fixed member may have a height larger than a vibration range of the diaphragm 20. Therefore, the vibration generating apparatus 5 may be coupled to a board, or the like, by the fixed member 40. At the same time, a vibration space of the diaphragm 20 may be secured.

However, the present exemplary embodiment is not limited thereto, but may be variously applied, if necessary. For example, covers may be coupled to upper and lower surfaces of the fixed member 40 to form the vibration space as a closed space.

As set forth above, since the vibration generating apparatus according to exemplary embodiments of the present disclosure may be formed in the disk shape rather than the bar shape, it may be miniaturized as compared with the related art. Therefore, the vibration generating apparatus may be easily mounted in a compact, thin portable terminal.

In addition, since the vibration generating apparatus according to an exemplary embodiment in the present disclosure may vibrate at the resonant frequency at which a user may best feel the tactile sensation in spite of having a small size, it may provide satisfactory touch feedback to a user.

While exemplary embodiments have been shown and described above, it will be apparent to those skilled in the art that modifications and variations could be made without departing from the scope of the present invention as defined by the appended claims.

What is claimed is:

1. A vibration generating apparatus comprising:
a diaphragm formed of a metal;
a piezoelectric plate mounted on at least one surface of the diaphragm;
a fixed member coupled to the diaphragm along an outer circumference of the diaphragm to fix the diaphragm; and
wherein the fixed member is formed of a material having a Young's modulus lower than that of steel.

2. The vibration generating apparatus of claim 1, wherein the fixed member is formed of rubber.

3. The vibration generating apparatus of claim 2, further comprising a housing coupled to the fixed member and accommodating the diaphragm in an internal space thereof.

4. The vibration generating apparatus of claim 2, wherein the vibration generating apparatus is a bimorph type piezoelectric element in which the piezoelectric plates are mounted on both surfaces of the diaphragm.

5. The vibration generating apparatus of claim 2, wherein the fixed member is a housing accommodating the diaphragm in an internal space thereof.

6. The vibration generating apparatus of claim 2, wherein the diaphragm is formed of a material having a Young's modulus lower than that of the steel.

7. The vibration generating apparatus of claim 2, wherein the diaphragm is formed of steel, brass, or Invar.

8. The vibration generating apparatus of claim 2, wherein a resonant frequency fr of vibrations generated by the diaphragm and the piezoelectric plate satisfies the following Conditional Equation 1:
150 Hz≦fr≦500 Hz Conditional Equation 1

9. The vibration generating apparatus of claim 2, wherein a thickness Dt of the diaphragm satisfies the following Conditional Equation 2:
0.06 mm≦Dt≦0.1 mm Conditional Equation 2

10. The vibration generating apparatus of claim 2, wherein the diaphragm is formed in a disk shape.

11. The vibration generating apparatus of claim 10, wherein the piezoelectric plate is formed in a disk shape having concentricity with respect to the diaphragm.

12. The vibration generating apparatus of claim 10, wherein the fixed member is formed in a circular ring shape corresponding to a shape of the outer circumference of the diaphragm.

13. A vibration generating apparatus comprising:
a diaphragm formed of a metal and formed to a thickness of 0.1 mm or less;
a piezoelectric plate mounted on at least one surface of the diaphragm; and
a fixed member coupled to the diaphragm along an outer circumference of the diaphragm to fix the diaphragm,
wherein the diaphragm is formed of a material having a Young's modulus lower than that of steel.

14. The vibration generating apparatus of claim 13, wherein the diaphragm is formed of brass or Invar.
